(19) United States
(12) Patent Application Publication
(10) Pub. No.: US 2025/0038013 A1
(43) Pub. Date: Jan. 30, 2025

(54) DUAL CHANNEL FLOW PLATE FOR WET PROCESSING

(71) Applicant: Yield Engineering Systems, Inc., Fremont, CA (US)

(72) Inventors: Vladimir Kudriavtsev, Palo Alto, CA (US); Rajeev Bajaj, San Jose, CA (US); Christopher Lane, Los Gatos, CA (US); Kevin McGillivray, Agua Dulce, CA (US); Sossan Wali, Moorpark, CA (US); Bob Hanopulus; Hratch Mouradian, Porter Ranch, CA (US)

(73) Assignee: Yield Engineering Systems, Inc., Fremont, CA (US)

(21) Appl. No.: 18/227,025

(22) Filed: Jul. 27, 2023

(51) Int. Cl. H01L 21/67; C23C 18/16; C23C 18/40

(52) U.S. Cl. CPC H01L 21/67023; C23C 18/1628; C23C 18/405

(57) ABSTRACT

An apparatus for wet chemical processing includes a processing tank that configured to contain a liquid chemical composition and support a plurality of substrates in the liquid chemical composition. A flow plate may be disposed in the processing tank below the plurality of substrates. The flow plate may include a plurality of liquid nozzles configured to direct the liquid chemical composition into the tank and a plurality of gas outlets configured to direct a gas into the tank.

### TECHNICAL FIELD

The present disclosure relates to an apparatus for wet chemical processing.

### BACKGROUND

Wet processes, or wet chemical processes, are used in many stages during the fabrication of semiconductor devices. Such wet chemical processes include, for example, etching, plating, cleaning, and other processes where a wafer or another substrate is disposed (e.g., submerged) in a chemical solution. During some wet processing steps, such as electroless copper deposition, etching, etc. it is important to deliver a gas to the bottom of the tank. The gas is discharged into the chemical solution in a processing tank through multiple holes and forms bubbles that rise upwards between the wafers, panels, devices, etc. (generally referred as “substrates” herein) that are positioned in the tank for processing. During processing (e.g., plating), byproduct of chemical reactions form bubbles (e.g., hydrogen bubbles) on the substrate surface that block access for the chemical solution to these areas and detrimentally affect film growth. The gas delivered to the bottom of the tank may form bubbles that help to deliver oxygen (or other neutral gases) to the substrate surface, dislodge byproducts of chemical reactions from the substrate surface, or create pressure waves to inject flow inside crevices or vias on the substrate surface. The gas discharged into the liquid may also transfer momentum to the liquid flow between the substrates thereby helping the transport of byproducts and precursors from the boundary layer on the substrate surface. Generally, the gas discharged into the tank may be said to be creating randomness (similar to turbulence) in the chemical solution that improves or advances wet processing. For example, the rising bubbles push the liquid in different directions as they move and, as a result, create pressure waves and pulsations in the liquid. These pulsations may disrupt the boundary layer on the substrate surfaces and create additional mixing of the liquid near these surfaces. Thus gas delivery into wet processing tanks serves a significant role in a wet chemical process. Conventionally, spargers (or sparger pipes) are used to inject a gas into a wet processing tank. However, sprager-type tanks may require space under the substrate basket to integrate an elaborate system of gas distribution pipes. Tanks that use laminar flow plates to direct chemical solution into the tank may have no space to place such gas distribution pipes. Locating sprager pipes between the laminar flow plate and the substrates may undesirably block the chemical solution from free access to the space between substrates. The apparatus and methods of the current disclosure may alleviate at least some of the above-described deficiencies. However, the scope of the current disclosure is defined by the claims and not by its ability to solve any problem.

### SUMMARY

Embodiments of an apparatus for wet chemical processing of substrates and related methods are disclosed.

In one embodiment, an apparatus for wet chemical processing of a plurality of substrates is disclosed. The apparatus includes a processing tank configured to contain a liquid chemical composition and support the plurality of substrates in the liquid chemical composition. A flow plate may be disposed in the liquid chemical composition in the processing tank such that, when the plurality of substrates are supported in the liquid chemical composition, the flow plate is positioned below the plurality of substrates. The flow plate may include a plurality of liquid nozzles configured to direct the liquid chemical composition towards the plurality of substrates, and a plurality of gas outlets configured to direct a gas towards the plurality of substrates.

Various embodiments of the disclosed apparatus may additionally or alternatively include one of more of the following features: the flow plate may be configured such that a flow rate of the gas directed into the tank and the flow rate of the liquid chemical composition directed into the tank can be independently varied; the plurality of liquid nozzles and the plurality of gas outlets may be evenly spaced apart on the flow plate; a discharge opening of each liquid nozzle of the plurality of liquid nozzles may have a diameter between about 0.05 inches to 0.1 inches; a discharge opening of each gas outlet of the plurality of gas outlets may have a diameter between about 0.02 inches to 0.06 inches; the flow plate may be configured such that a flow rate of the gas through the plurality of gas outlets is less than about 50% of the flow rate of the liquid chemical composition through the plurality of liquid nozzles; a number of liquid nozzles in the plurality of liquid nozzles is same as the number of gas outlets in the plurality of gas outlets.

Various embodiments of the disclosed apparatus may additionally or alternatively include one of more of the following steps or features: a pitch of the plurality of liquid nozzles and plurality of gas outlets may be 1/N times a pitch of plurality of substrates in the tank, where N is any value greater than or equal to one; a pitch of the plurality of liquid nozzles is between about 0.05-1 inch in a length direction of the flow plate; the pitch of the plurality of liquid nozzles in a width direction of the flow plate and the pitch of the plurality of liquid nozzles in the length direction of the flow plate may be the same; the pitch of the plurality of gas outlets may be between about 0.05-1 inch in the length direction of the flow plate; the pitch of the plurality of gas outlets in the width direction of the flow plate and the pitch of the plurality of gas outlets in the length direction of the flow plate may be the same; the plurality of liquid nozzles and the plurality of gas outlets may be arranged in alternating linear arrays; the alternating linear arrays may extend in a length direction of the flow plate; the plurality of liquid nozzles and the plurality of gas outlets may be arranged to form multiple nested zones that can be independent controlled; each nested zone of the multiple nested zones may include one or more liquid nozzles and one or more gas outlets; each nested zone of the multiple nested zones may include only one of liquid nozzles or gas outlets; the plurality of liquid nozzles and the plurality of gas outlets may be arranged on a top surface of the flow plate; the flow plate may form a base of the processing tank; the apparatus may be an electroless copper plating apparatus.

In another embodiment, a method of wet chemical processing a plurality of substrates is disclosed. The method includes positioning a plurality of substrates in a processing tank containing a liquid chemical composition. The method may also include directing the liquid chemical composition into the processing tank through a plurality of liquid nozzles of a flow plate positioned below the plurality of substrates, and directing a gas into the processing tank through a plurality of gas outlets of the flow plate.

Various embodiments of the disclosed apparatus may additionally or alternatively include one of more of the following steps or features: directing the liquid chemical composition and directing the gas may include simultaneously directing the liquid chemical composition and the gas into the processing tank; the plurality of substrates may be positioned in the processing tank after simultaneously directing the liquid chemical composition and the gas into the processing tank; directing the liquid chemical composition into the processing tank may include directing a pulsating flow of the liquid chemical composition into the processing tank; directing the gas into the processing tank includes directing a pulsating flow of the gas into the processing tank.

### BRIEF DESCRIPTION OF THE DRAWINGS

The accompanying drawings, which are incorporated herein and constitute a part of this disclosure, illustrate exemplary embodiments and, together with the description, are used to explain the disclosed principles. In these drawings, where appropriate, reference numerals that illustrate the same or similar structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure of the various described embodiments. Details of well-known components or features may be omitted to avoid obscuring other features, since these omitted features are well-known to those of ordinary skill in the art. Further, features in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing dimensions or proportional relationships between different features in a figure. Additionally, even if it is not expressly mentioned, aspects described with reference to one embodiment or figure may also be applicable to, and may be used with, other embodiments or figures.

FIG. 1 is a schematic illustration of an exemplary wet chemical processing apparatus of the current disclosure;

FIGS. 2A-2C are schematic sectional side views of exemplary integrated flow plates that may be used in the wet chemical processing apparatus of FIG. 1;

FIGS. 3A-3G are schematic top views of exemplary integrated flow plates that may be used in the wet chemical processing apparatus of FIG. 1;

FIG. 4A is a sectional side view of a portion of an exemplary integrated flow plate of the current disclosure;

FIG. 4B is a perspective view of another exemplary flow plate of the current disclosure; and

FIG. 5 is a flow chart illustrating an exemplary method of using the apparatus of FIG. 1.

### DETAILED DESCRIPTION

All relative terms such as “about,” “substantially,” “approximately,” etc., indicate a possible variation of +10% (unless noted otherwise or another degree of variation is specified). For example, a feature disclosed as being about “t” units wide (or length, thickness, depth, etc.) may vary in width from (t−0.1 t) to (t+0.1 t) units. In some cases, the specification also provides context to some of the relative terms used. For example, a structure described as being substantially linear may deviate by +10% from being linear. Further, a range described as varying from, or between, 5 to 10 (5-10), includes the endpoints (i.e., 5 and 10).

Unless otherwise defined, all terms of art, notations, and other scientific terms or terminology used herein have the same meaning as commonly understood by persons of ordinary skill in the art to which this disclosure belongs. Some components, structures, and/or processes described or referenced herein are well understood and commonly employed using conventional methodology by those skilled in the art. These components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in references incorporated by reference. None of the references described or referenced herein is admitted as prior art relative to the current disclosure.

The discussion below describes an exemplary apparatus and method that may be used for wet chemical processing of a substrate. Wet chemical processing is used for a variety of purposes—from chemical removal of material (wet etching) to deposition of material (electroplating), to sample cleaning, to the creation of patterns on the surface using optical lithography techniques-during the fabrication of semiconductor and photonic devices. As mentioned previously, the term “substrate” is used to generally refer to parts, such as, for example, wafers, panels, IC device(s), printed circuit boards (PCBs), semiconductor packages, etc. that may be subject to some type of wet chemical processing, for example, during fabrication. Although embodiments of the current disclosure may be used with any wet processing apparatus, in the discussion below, some aspects of the current disclosure will be described with reference to a processing bath or tank used for electroless copper plating. However, this is only exemplary and embodiments of the current disclosure may be used with any wet chemical processing apparatus. Electroless copper plating is a chemical process that deposits an even layer of copper on the surface of a solid substrate, like glass, metal or plastic. The process may involve dipping one or more substrates in a water solution containing copper salts and a reducing agent such as formaldehyde. Unlike electroplating, electroless plating processes in general do not require passing an electric current through the bath and the substrate. The reduction of the metal cations in solution is achieved by purely chemical means, through an autocatalytic reaction.

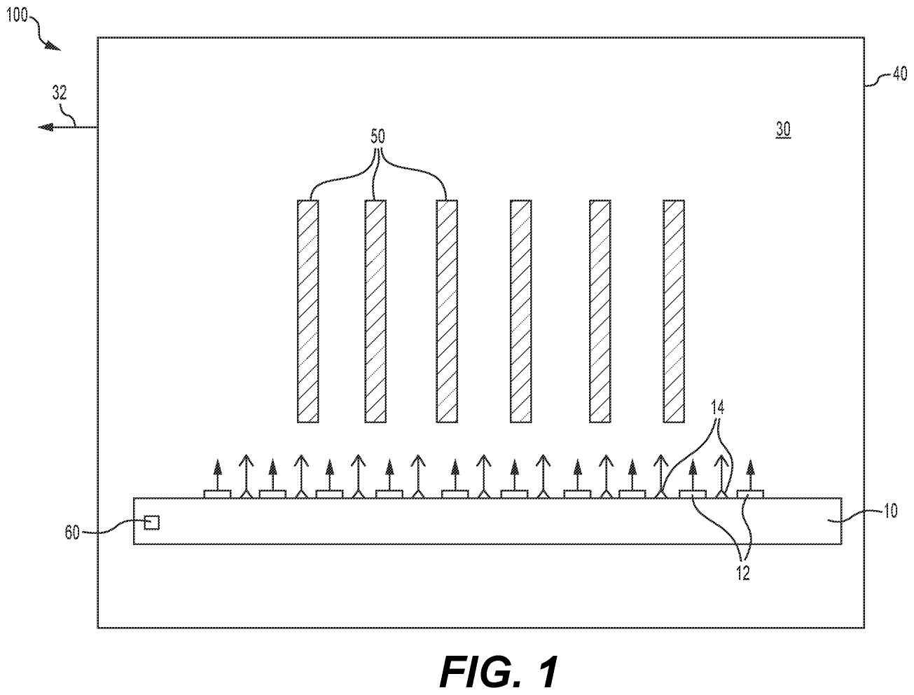

FIG. 1 is a schematic illustration of an exemplary wet processing apparatus 100 of the current disclosure. In some embodiments, apparatus 100 may be an electroless plating apparatus. A plurality of substrates 50 may be disposed in a plating liquid 30 in a plating tank 40 of apparatus 10. In general, at least the portion of substrates 50 that are to be plated may be submerged in plating liquid 30. Typically, adjacent substrates of the plurality of substrates 50 may be spaced apart to allow plating liquid 30 to flow between the spaces and treat the exposed surfaces of the substrates 50. During operation, plating liquid in tank 40 may be removed from tank 40 through an outlet 32. In some embodiments, the removed plating liquid may be treated (e.g., cleaned, filtered, etc.) and returned to tank 40 through a flow plate 10 as discussed below. In some applications, the liquid directed to tank 40 may also be heated (or cooled) to a desired temperature. Although not shown in FIG. 1, in addition to plating tank 40, apparatus 100 may include other baths or tanks, such as for example, a pre-plating treatment bath, a collecting bath, and a rinsing bath, configured to perform different steps in the plating process. In some embodiments, the plurality of substrates 50 may move from one bath to another on, for example, rails. The composition of plating liquid 30 in tank 40 depends on the application. In some embodiments of electroless copper plating, the plating liquid may be a water solution containing copper salts and a reducing agent such as formaldehyde. However, this is not a requirement, and any now-known or later-developed plating solution may be used as plating liquid 30.

Tank 40 may include an integrated flow plate 10 disposed in plating liquid 30. In some embodiments, as illustrated in FIG. 1, flow plate 10 may be positioned below the plurality of substrates 50 in tank 40. In some embodiments, flow plate 10 may be positioned on (e.g., coupled to, attached to, etc.) the underside of the tank 40 such that flow plate 10 forms the base of tank 40. Flow plate 10 may be configured to simultaneously supply separate streams (e.g., without mixing) of plating liquid 30 and a gas into plating tank 40. In some embodiments, the flow plate may be configured to direct the plating liquid and the gas over an entire area of the substrates 50 in tank 40. In some embodiments, flow plate 20 may be configured to direct the plating liquid and the gas over the entire area of the base of the tank. Flow plate 10 may include a plurality of liquid nozzles 12 (or outlets) configured to direct plating liquid 30 into tank 40 and a plurality of gas outlets 14 configured to direct a separate stream of a gas into tank 40. The liquid nozzles 12 and gas outlets 14 may have their discharge openings on a top surface of flow plate 10 facing the plurality of substrate 50. In some embodiments, liquid nozzles 12 and gas outlets 14 may be configured to direct the discharged liquid and gas towards the plurality of substrates 50 in tank 40. Any type of a gas (e.g., air, oxygen, nitrogen, an inert gas, etc.) may be directed into tank 40 through gas outlets 14. In some embodiments, liquid nozzles 12 and gas outlets 14 may be arranged in pairs such that the number of liquid nozzles 12 and gas outlets 14 are the same. In some embodiments, liquid nozzles 12 and gas outlets 14 may be interdigitated orifices for directing separate streams of the plating liquid and the gas simultaneously from the underside of the tank.

The gas exiting gas outlets 14 into the liquid in tank 40 forms bubbles that rise up through the space between the substrates 50 in the tank 40. The flow around the rising bubbles, and the flow in the space between the substrates 50, may be laminar. The rising bubbles may however push the liquid in different directions and create pressure waves and pulsations that may disrupt the boundary layer (on the substrate surfaces) and create additional mixing of the liquid in the space between the substrates 50. In an electroless process, these pressure waves may also assist in dislodging bubbles of hydrogen that form on the surface of the substrates due to the electroless process. The bubbles may be of any size. In some embodiments, the bubbles may have a distribution of different sizes (e.g., between 50-200 microns, 1-4 mm, etc.) and may grow in size as they rise to the surface.

Although the liquid directed into tank 40 through liquid nozzle 12 is described as the plating liquid, in general, any liquid may be directed into the tank through nozzles 12. For example, when tank 40 is used for etching, an etching solution may be admitted into tank through nozzles 12, and a gas that assists in the etching process may be directed through gas outlets 14. Flow plate 10 may be configured to enable independent control of the gas and the liquid flow rate into tank 40. In other words, the flow rates of the gas and the liquid exiting the flow plate into the tank may be independently controllable or tunable. In some embodiments, flow plate 10 may be configured such that the flow rate of the gas into tank 40 (through gas outlets 14) is less than about 50% (equivalent standard liter per minute (SLPM)) of the liquid flow rate into tank 40 (through liquid nozzles 12).

In general, (the openings of) liquid nozzles 12 and gas outlets 14 may have any size. In some embodiments, the liquid nozzle openings may have a size (e.g., diameter) between about 0.05 inches to 0.1 inches, and the gas outlet openings may have a size (e.g., diameter) between about 0.02 inches to 0.06 inches. In some embodiments, the gas outlets 14 may have a size (e.g., diameter) between about 0.02 inches to 0.08 inches. Although not a requirement, in some embodiments, each liquid nozzle 12 may have the same size opening and each gas nozzle 14 may have the same size opening. In some embodiments, the size of the discharge openings of both liquid nozzles 12 and gas outlets 14 may be the same. In some embodiments, liquid nozzles 12 may be larger than gas outlets 14.

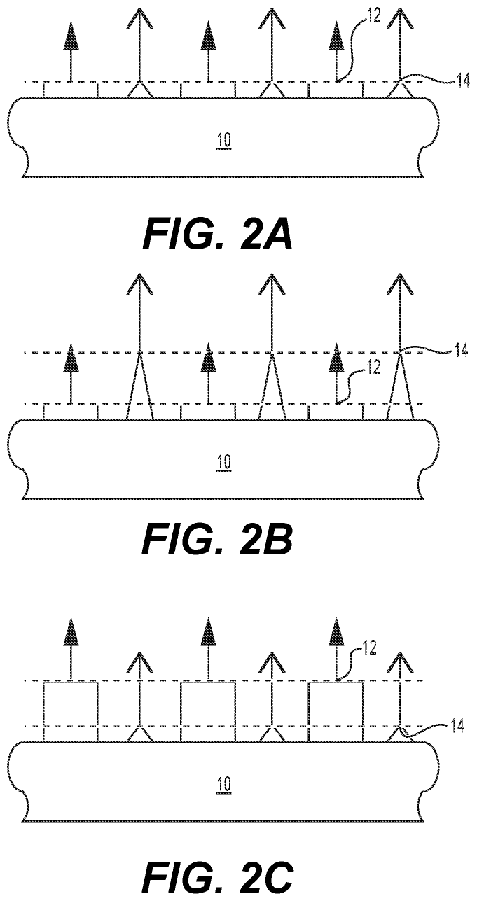

In some embodiments, as schematically illustrated in FIG. 2A, the openings of liquid nozzles 12 and gas outlets 14 of flow plate 10 may be on a same plane. For example, the openings of the liquid nozzles 12 and the gas outlets 14 may be at a same height below the substrates such that both the liquid and the gas are admitted into the tank at a same distance below the substrates. In some embodiments, as illustrated in FIG. 2B, the openings of gas outlets 14 may be higher than the opening of the liquid nozzles 12 such that the liquid is admitted into tank 40 below the gas. In some embodiments, as illustrated in FIG. 2C, the openings of liquid nozzles 12 may be higher than the gas outlets 14 such that the gas is admitted into tank 40 below the liquid. The liquid nozzles 12 and gas outlets 14 may be vertically spaced apart by any distance. In some embodiments, liquid nozzles 12 and gas outlets 14 may be vertically spaced apart by between about 0.1-0.5 inch. In some embodiments, the vertical position of the liquid nozzles 12 and/or the gas outlets 14 on flow plate 10 may be adjustable such that the vertical gap between the openings of the liquid nozzles 12 and the gas outlets 14 may be varied (e.g., between about 0.25 to 1 inch).

In general, liquid nozzles 12 and gas outlets 14 may be arranged in any pattern on flow plate 10. For example, in some embodiments, gas outlets 14 may be arranged such that gas bubbles are concentrated on the side of the substrates where the desired processing occurs. For example, if tank 40 is used for a copper electroless deposition process, for example, to deposit copper on one side of the substrates 50, the gas outlets 14 on flow plate 10 may be arranged such that the gas bubbles are concentrated on the side of the substrate 50 where copper deposition is desired. In some embodiments, the gas outlets 14 may be arranged on flow plate 10 such that gas bubbles rise through the space between the substrates 50 with minimal obstruction by the substrates 50.

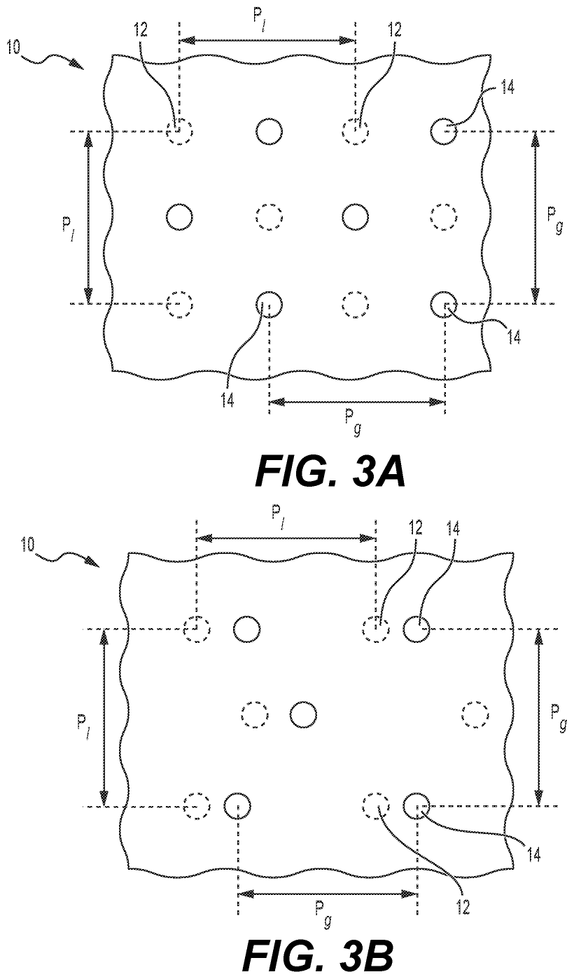

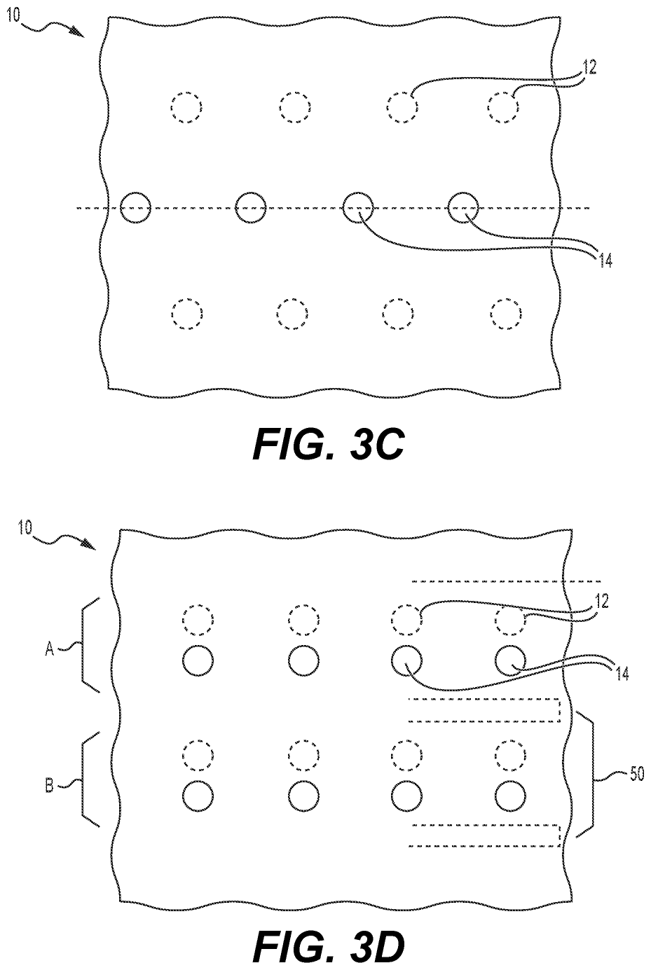

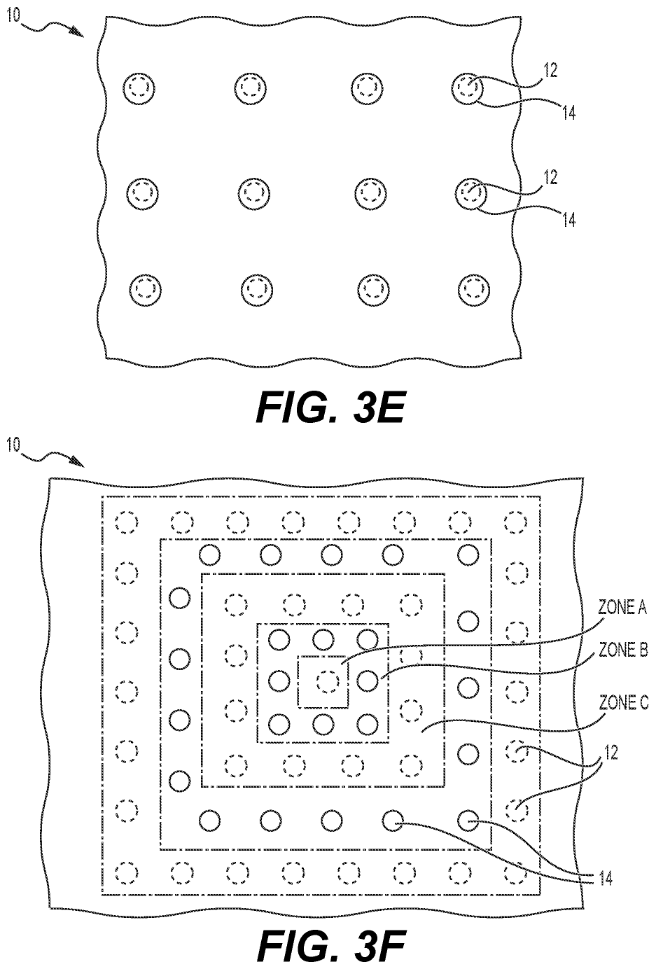

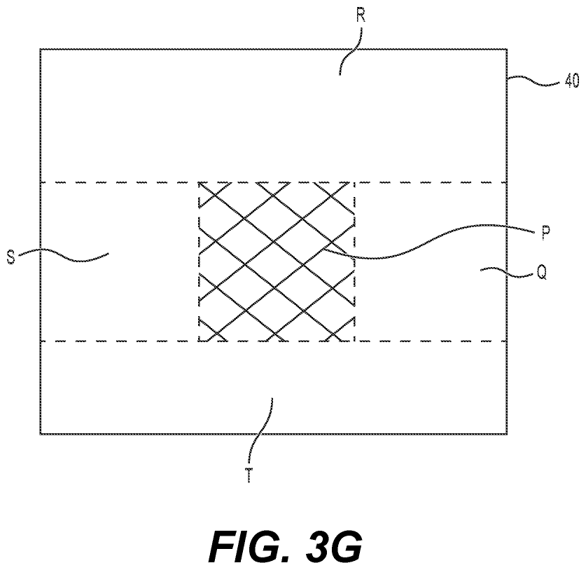

Liquid nozzles 12 and gas outlets 14 may be arranged in any pitch on flow plate 10. In some embodiments, the pitch between liquid nozzles 12, and the pitch between gas outlets 14, may be about (1/N) times the pitch of substrates 50 in tank 40 (or substrate pitch), where N≥1. In some embodiments, the pitch of the openings (of both the liquid nozzles and the gas outlets) in flow plate 10 may be about (1/N) times the substrate pitch. In general, the substrate pitch may vary with application. In some embodiments, the substrate pitch may be between about 10-25 mm (about 0.39-0.98 inches). FIGS. 3A-3F illustrate a plan view of flow plate 10 with exemplary layouts of liquid nozzles 12 and gas outlets 14. In some embodiments, as illustrated in FIG. 3A, the liquid nozzles 12 may have an pitch P_{L} of between about 0.05-1 inch and gas outlets 14 may have a pitch P_{G} between about 0.05-1 inch in at least one direction (e.g., along the length direction of flow plate 10). In some embodiments, pitch P_{L} of liquid nozzles 12 and pitch P_{G} of gas outlets 14 may be the same in both the length and width direction of flow plate 10. In some embodiments, the liquid nozzles 12 and gas outlets 14 may be evenly spaced apart and have a constant pitch in both the length and width directions of flow plate 10. In other words, with reference to FIG. 3A, P_{L} and P_{G} may be about the same, and the spacing between adjacent liquid nozzles 12 and gas outlets 14 may be about P_{L}/2 (or P_{G}/2). In some embodiments, as illustrated in FIG. 3B, liquid nozzles 12 may have a constant pitch P_{L}, and gas nozzles 14 may have a constant pitch P_{G}, in at least one direction, but the gas outlets 14 may be positioned closer to the liquid nozzles 12. For example, P_{L} and P_{G} may be about the same, and the spacing between adjacent liquid nozzles 12 and gas outlets 14 may be less than P_{L}/2 (or P_{G}/2). In some embodiments, pitch P_{L} and/or P_{G} may vary across the flow plate. For example, in some embodiments, liquid nozzles 12 and/or gas outlets 14 may be closer together at the center of flow plate 10 than at its edges. In some embodiments, liquid nozzles 12 and/or gas outlets 14 may be closer together at the edges (or corners) of flow plate 10 than at its center.

In some embodiments, as illustrated in FIG. 3C, liquid nozzles 12 and gas outlets 14 may be arranged in alternating linear arrays. In some embodiments, each linear array may extend in the same direction as the substrates 50 in tank 40 (see, e.g., FIG. 3D) or the length direction of tank 40. In some embodiments, the linear arrays may extend in the width direction of tank 40. The liquid nozzles 12 and/or gas outlets 14 of each array may also be tuned independently. For example, the flow rate of the liquid exiting liquid nozzles 12 (or gas exiting gas outlets 14) through one array may be varied independent of other nozzles 12 (or openings 14). In some embodiments, as illustrated in FIG. 3D, liquid nozzles 12 and gas outlets 14 may be arranged in alternating linear arrays, and the liquid nozzles 12 and gas outlets 14 may be spaced apart such pairs of liquid nozzles 12 and gas outlets 14 are positioned in between adjacent substrates 50 in tank 40. In some embodiments, similar to the embodiment of FIG. 3C, each array be tuned independently. In some embodiments, the flow rate of fluid exiting each adjacent pair of liquid nozzles 12 and gas openings 14 (marked A and B in FIG. 3D) may be varied together independent of other pairs.

In some embodiments, as illustrated in FIG. 3E, each gas outlet 14 may extend around a liquid nozzle 14 (or vice versa). In other words, gas outlet 14 may be an annular opening around a liquid nozzle 12 such that the liquid discharged into the tank is surrounded by the gas. In some embodiments, liquid nozzle 12 may be an annular opening around gas outlet 14 such that the liquid surrounds the gas. These concentric openings may have any of above-described pitch.

In some embodiments, as illustrated in FIG. 3F, the openings (liquid nozzles and air outlets) in flow plate 10 may be arranged as nested quadrangles or rectangles to form different zones that may be independently tuned. In other words, the flow rate of the fluid (liquid or gas) entering tank 40 through zones A, B, C, and D may be independently varied. In some embodiments, each zone may include a mix of liquid nozzles 12 and gas outlets 14. For example, zones A, B, C, and D may include both liquid nozzles 12 and gas outlets 14 arranged to form alternating openings or arranged in another pattern. In some embodiments, as illustrated in FIG. 3F, each zone may include only one of liquid nozzles 12 or gas outlets 14. In other words, each zone may include either liquid nozzles 12 or gas outlets 14. In some embodiments, some zones (e.g., zones A and B) may include both liquid nozzles 12 and gas outlets 14 while other zones may include only liquid nozzles 12 or gas outlets 14.

With reference to FIG. 3G, in some embodiments, the size and/or spacing between liquid nozzles 12 and gas outlets 14 may be such that the flow rate of the liquid and/or gas in the region (marked P) under the substrates 50 (or a basket carrying the substrates) is different from regions outside (marked Q, R, S, T). For example, in some embodiments, the size of liquid nozzles 12 and/or gas outlets 14 in region P may be larger (or smaller) from those in the other regions (e.g., regions Q, R, S, T). Alternatively or additionally, in some embodiments, liquid nozzles 12 and gas outlets 14 may be spaced closer together (or further apart) in region P than in the other regions. In some embodiments, the size and/or spacing between liquid nozzles 12 and gas outlets 14 in regions Q, R, S, T may be the same and different from that in region P. In some embodiments, the size and/or spacing between liquid nozzles 12 and gas outlets 14 in some or all of regions Q, R, S, T may also be different. Using the different sized (and/or differently spaced) liquid nozzles 12 and gas outlets 14 in regions P, Q, R, S, and T, the flow rate of the fluid (liquid or gas) entering tank 40 through these different regions may be independently varied. It is also contemplated that, in some embodiments, liquid nozzles 12 and gas outlets 14 may only be provided in region P.

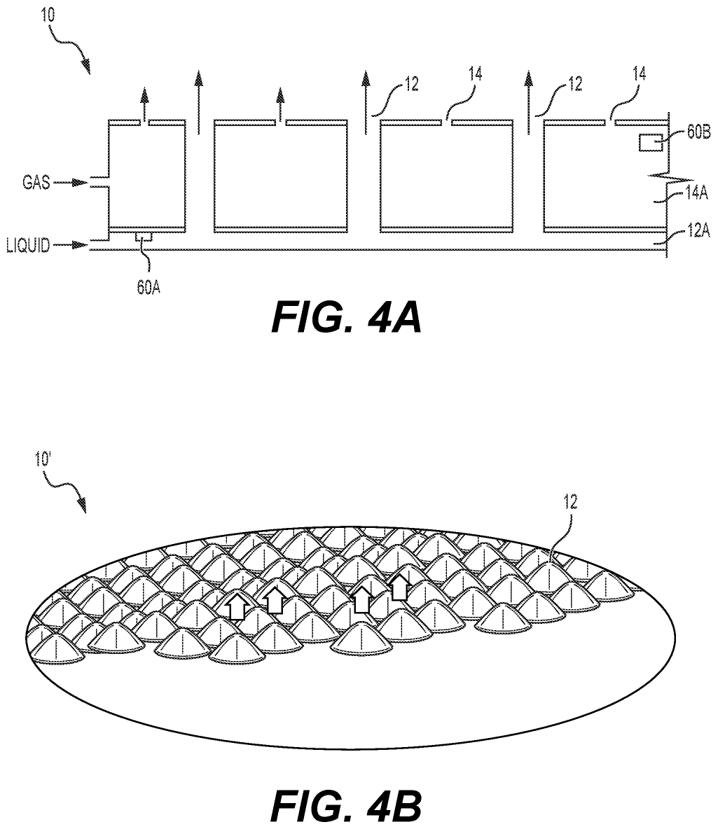

Flow plate 10 may optionally include temperature control (e.g., one or more heaters 60) so that liquids and gases may be heated to predetermined temperatures before directed into tank 40. The size of flow plate 10 may depend on the application (e.g., the size of tank 40, size of substrates 50, number of substrates 50, etc.). In one exemplary embodiment, twelve (12) substrates spaced apart by between about 10 mm-25 mm (about 0.39-0.98 inches), with each substrate having a size of about 510 mm×515 mm (about 20.07×20.27 inches) may be positioned in a tank having a length of about 27 inches, a width of about 15 inches, and a height of about 24 inches. In such an embodiment, flow plate 20 may have a size substantially equal to (or slightly smaller than) the size of the tank 70. In other words, flow plate 10 may have a length slightly less than 27 inches and a width slightly less than 15 inches so the flow plate 10 may be snugly received in tank 70. In some embodiments, flow plate 10 may form the base of tank 40. Flow plate 10 may have any thickness. In some embodiments, the thickness of flow plate 10 may be between about 0.5-4.0 inches. It should be noted that a rectangular flow plate is merely exemplary. In general, flow plate 10 may have any shape (see, e.g., FIG. 4B). In some embodiments, the shape of flow plate 10 may depend on the shape of the tank of the wet processing apparatus. Flow plate 10 may be constructed of any suitable material such as, for example, Teflon, Perfluoroalkoxy alkanes (PFA), polypropylene, high density polyethylene (HDPE), or another suitable metal such as stainless steel, titanium etc.

Independent streams of liquid and gas may be directed through flow plate 10 in any known manner. FIG. 4A illustrates an exemplary flow plate 10 having independent liquid and gas channels 12A, 14A for directing separate liquid and gas streams through liquid nozzles 12 and gas outlets 14, respectively. In some embodiments, one or more heaters 60A, 60B may be positioned in the liquid and/or gas channel 12A, 14A to heat the fluid passing through that channel. In some embodiments, liquid and/or gas channel 12A, 14A may include multiple independent conduits configured to direct different flow rates of liquid and/or gas through selected nozzles 12 and/or outlets 14. For example, the body of the flow plate may be hollow in its entirety or may include a labyrinth of channels with orifice-like outlets directed into the tank so that both liquid and gas jets may exit into the upstream rising flow next to each other. This may promote mixing and allow different patterns of location, density, and mapping of gas and liquid holes depending on the application. In some embodiments, a hollow flow plate may be replaced by a combination of a densely packed array of smaller diameter tubes for gas delivery (for example, with tubes diameters being less that half of the distance between the substrates) and an array of orifices inside a solid laminar flow plate and with flow straighteners and baffle-like structures that are, for example, integrated with the upper surface of the laminar plate that faces the substrates in the tank.

FIG. 4B illustrates another embodiment of flow plate 10′ that may be used with some embodiments of wet processing apparatus. Flow plate 10′ has a circular shape and includes a plurality of liquid nozzles 12 disposed on one of its surfaces. A liquid may be directed into the tank of the apparatus through liquid nozzles 12. In some embodiments of flow plates, as illustrated in flow plate 10′ of FIG. 4B, separate gas openings 14 may be eliminated. In some embodiments, nozzles 12 may also direct a gas into the tank. For example, nozzles 12 may discharge a liquid into the tank for a preselected time and then discharge a gas for a preselected time (or vice versa). In some embodiments, gas openings (e.g., similar to the gas openings disclosed with reference to the previous embodiments) may be interspersed with liquid openings 12 on flow plate 10′. The size, pitch, and layout of the liquid nozzles 12 and gas openings 14 may be similar to those disclosed previously.

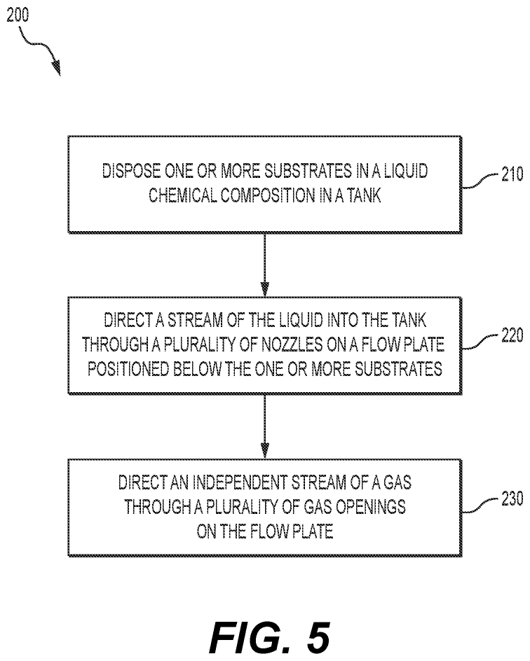

FIG. 5 is a flow chart of an exemplary process 200 of using a disclosed wet processing apparatus. One or more substrates may be disposed in a tank of the wet processing apparatus containing a liquid chemical composition. (Step 210). As explained previously, the chemical composition contained in the tank depends on the application. In some embodiments, the one or more substrates may be at least partially submerged in the liquid in the tank. In some embodiments, a plurality of substrates may be spaced apart from each other at a pitch (constant or variable pitch) and disposed in the tank. The substrates may be spaced apart such that adjacent substrates are spaced apart from each other. A stream of the liquid (the same liquid as that in the tank) may then be directed into the tank through a plurality of openings or nozzles of a flow plate positioned below the substrates in the tank. (Step 220). An independent stream of a gas may also be directed into the tank through a plurality of gas openings interspersed with the liquid nozzles on the flow plate. (Step 230). In some embodiments, the liquid and the gas may be directed from the flow plate towards the substrates. For example, the liquid nozzles and the gas outlets may be positioned on a top surface of the flow plate that faces the one or more substrates such that the liquid and gas exiting the flow plate are directed towards the substrates. In some embodiments, the liquid and gas may be discharged into the processing tank simultaneously. In some embodiments, the substrates may be disposed in the tank after the liquid and the gas are directed into the tank through the flow plate. In other words, step 210 may be performed after steps 220 and 230 have begun. The flow rate of the liquid and/or the gas into the tank through the flow plate may be independently varied. In some embodiments, the flow rate of the liquid and/or the gas into the tank through the flow plate may be constant or steady. In some embodiments, the liquid may be directed into the tank through the flow plate (i.e., step 220) in a pulsating manner. Additionally or alternatively, in some embodiments, the gas may be directed into the tank through the flow plate (i.e., step 230) in a pulsating manner. As used herein, a pulsating or oscillating flow (as opposed to a constant flow) refers to fluid flow with periodic variations in the flow rate of the fluid. The flow rate may oscillate in a rhythmic or a random manner. Discharging the gas along with the liquid into the tank through the flow plate positioned below the substrates may disrupt the boundary layer at substrate surfaces and improve the processing of the substrates. Any wet chemical process (e.g., electroless plating, etching, cleaning, etc.) may be performed using process 200. The type of liquid and gas used in process 200 may depend on the application (e.g., electroless plating, etching, cleaning, etc.) that process 200 is used in.

Wet chemical processes such as, for example, electroless copper plating is a mass transfer (or kinetic transport) limited process. At low deposition rates, copper at the interface between the plating liquid and the substrate surface can be replenished thru diffusion. However, as deposition rates exceed diffusion rates, deposition rate may decrease and even drop to zero. This decreasing deposition rate is especially problematic when plating narrow features with a high aspect ratio where plating liquid replenishment is adversely affected due to the geometry of the structure. Using the disclosed flow plate with integrated liquid and gas outlets enables the creation of a random or turbulent flow that is uniform throughout the tank and enables the replenishment of the plating liquid (or other liquid used) in all areas on the substrate surface thereby improving the plating process.

Although the current disclosure is described with reference to a wet processing apparatus for electroless plating, this is only exemplary. Persons of ordinary skill in the art would recognize that the disclosed apparatus can be used for any wet processing application. Furthermore, although some features were disclosed with reference to specific embodiments, a person skilled in the art would recognize that this is only exemplary, and the features are applicable to all disclosed embodiments. Other embodiments of the apparatus, its features and components, and related methods will be apparent to those skilled in the art from consideration of the disclosure herein.

What is claimed is:

1. An apparatus for wet chemical processing of a plurality of substrates, comprising:
a processing tank configured to contain a liquid chemical composition and support the plurality of substrates in the liquid chemical composition; and
a flow plate disposed in the liquid chemical composition in the processing tank such that, when the plurality of substrates are supported in the liquid chemical composition, the flow plate is positioned below the plurality of substrates, and wherein the flow plate includes,
a plurality of liquid nozzles configured to direct the liquid chemical composition towards the plurality of substrates; and
a plurality of gas outlets configured to direct a gas towards the plurality of substrates.

2. The apparatus of claim 1, wherein the flow plate is configured such that a flow rate of the gas directed into the tank and the flow rate of the liquid chemical composition directed into the tank can be independently varied.

3. The apparatus of claim 1, wherein the plurality of liquid nozzles and the plurality of gas outlets are evenly spaced apart on the flow plate.

4. The apparatus of claim 1, wherein a discharge opening of each liquid nozzle of the plurality of liquid nozzles have a diameter between about 0.05 inches to 0.1 inches.

5. The apparatus of claim 4, wherein a discharge opening of each gas outlet of the plurality of gas outlets have a diameter between about 0.02 inches to 0.06 inches.

6. The apparatus of claim 1, wherein the flow plate is configured such that a flow rate of the gas through the plurality of gas outlets is less than about 50% of the flow rate of the liquid chemical composition through the plurality of liquid nozzles.

7. The apparatus of claim, wherein a number of liquid nozzles in the plurality of liquid nozzles is same as the number of gas outlets in the plurality of gas outlets.

8. The apparatus of claim 1, wherein a pitch of the plurality of liquid nozzles and plurality of gas outlets is 1/N times a pitch of the plurality of substrates, and wherein N is any value greater than or equal to one.

9. The apparatus of claim 1, wherein a pitch of the plurality of liquid nozzles is between about 0.05-1 inch in a length direction of the substrate.

10. The apparatus of claim 9, wherein the pitch of the plurality of liquid nozzles in a width direction of the flow plate and the pitch of the plurality of liquid nozzles in the length direction of the flow plate are the same.

11. The apparatus of claim 9, wherein the pitch of the plurality of gas outlets is between about 0.05-1 inch in the length direction of the flow plate.

12. The apparatus of claim 11, wherein the pitch of the plurality of gas outlets in the width direction of the flow plate and the pitch of the plurality of gas outlets in the length direction of the flow plate are the same.

13. The apparatus of claim 1, wherein the plurality of liquid nozzles and the plurality of gas outlets are arranged in alternating linear arrays.

14. The apparatus of claim 13, wherein each array of the alternating linear arrays extend in a length direction of the flow plate.

15. The apparatus of claim 1, wherein the plurality of liquid nozzles and the plurality of gas outlets are arranged to form multiple nested zones that can be independent controlled.

16. The apparatus of claim 15, wherein each nested zone of the multiple nested zones includes one or more liquid nozzles and one or more gas outlets.

17. The apparatus of claim 15, wherein each nested zone of the multiple nested zones includes only one of liquid nozzles or gas outlets.

18. The apparatus of claim 1, wherein the plurality of liquid nozzles and the plurality of gas outlets are arranged on a top surface of the flow plate.

19. The apparatus of claim 1, wherein the flow plate forms a base of the processing tank.

20. The apparatus of claim 1, wherein the apparatus is an electroless copper plating apparatus.

21. A method of wet chemical processing a plurality of substrates, comprising:
positioning a plurality of substrates in a processing tank containing a liquid chemical composition;
directing the liquid chemical composition into the processing tank through a plurality of liquid nozzles of a flow plate positioned below the plurality of substrates; and
directing a gas into the processing tank through a plurality of gas outlets of the flow plate.

22. The method of claim 21, wherein directing the liquid chemical composition and directing the gas includes simultaneously directing the liquid chemical composition and the gas into the processing tank.

23. The method of claim 22, wherein the plurality of substrates are positioned in the processing tank after simultaneously directing the liquid chemical composition and the gas into the processing tank.

24. The method of claim 21, wherein directing the liquid chemical composition into the processing tank includes directing a pulsating flow of the liquid chemical composition into the processing tank.

25. The method of claim 21, wherein directing the gas into the processing tank includes directing a pulsating flow of the gas into the processing tank.
